(19) United States
(12) Patent Application Publication
(10) Pub. No.: US 2024/0128285 A1
(43) Pub. Date: Apr. 18, 2024

(54) PHOTOELECTRIC CONVERSION DEVICE AND EQUIPMENT

(71) Applicant: CANON KABUSHIKI KAISHA, Tokyo (JP)

(72) Inventors: HIDEKI IKEDO, Kanagawa (JP); SATOSHI SUZUKI, Tokyo (JP)

(21) Appl. No.: 18/486,047

(22) Filed: Oct. 12, 2023

(30) Foreign Application Priority Data
Oct. 17, 2022 (JP) 2022-166156
Sep. 29, 2023 (JP) 2023-169953

(51) Int. Cl. H01L 27/146

(52) U.S. Cl. CPC H01L 27/14603; H01L 27/14612; H01L 27/14627

(57) ABSTRACT

A photoelectric conversion device comprises a pixel substrate. The pixel substrate includes a photoelectric conversion unit to generate signal charge according to incident light, a floating diffusion unit to receive the signal charge as input, a pixel transistor region including the floating diffusion unit, first and second output lines, and a first region and a second region located outside the first region. In a plan view relative to a main surface of the pixel substrate, the first region is where the first output line overlaps with at least a portion of the pixel transistor region, the second region is where the second output line overlaps with at least a portion of the photoelectric conversion unit, and an end portion of the second output line intersecting with respect to a longer-side direction of the second output line is positioned to overlap with at least a portion of the second region.

### BACKGROUND

### Field

The present disclosure relates to a photoelectric conversion device and equipment.

### Description of the Related Art

A photoelectric conversion device including a plurality of pixels is known in which signal charge generated in a photoelectric conversion unit is transferred to a floating diffusion (FD) unit, and a signal amplified by an amplifying transistor is output by each pixel. By increasing the number of output lines that output signals, the readout of signals from the pixels can be speeded up. As an example of a configuration with an increased number of output lines, Japanese Patent Laid-Open No. 2015-138862 discloses a solid-state imaging device having a configuration in which a plurality of output lines is provided for each pixel column.

In the case where the number of output lines is increased as in Japanese Patent Laid-Open No. 2015-138862, there is a high probability that a break will occur in any output line during the manufacturing process. As a result, the yield decreases. Also, in a configuration with a plurality of output lines, parasitic capacitance may occur between the FD unit and the plurality of output lines.

As a result, crosstalk occurs between signals from pixels that are read out in parallel.

### SUMMARY

The present disclosure provides a photoelectric conversion device capable of both improving yield and suppressing crosstalk.

According to an aspect of the present disclosure, a photoelectric conversion device comprises a pixel substrate, wherein the pixel substrate includes a photoelectric conversion unit configured to generate signal charge according to incident light, a floating diffusion unit configured to receive the signal charge as input, a pixel transistor region including the floating diffusion unit, a first output line configured to output a signal according to a potential of the floating diffusion unit, a second output line electrically connected to the first output line, a first region, in a plan view relative to a main surface of the pixel substrate, where the first output line overlaps with at least a portion of the pixel transistor region, and a second region, in the plan view relative to the main surface, located outside the first region and where the second output line overlaps with at least a portion of the photoelectric conversion unit, and wherein, in the plan view relative to the main surface, an end portion of the second output line intersecting with respect to a longer-side direction of the second output line is positioned to overlap with at least a portion of the second region.

Further features of the present disclosure will become apparent from the following description of exemplary embodiments with reference to the attached drawings.

### BRIEF DESCRIPTION OF THE DRAWINGS

FIG. 1 is a block diagram illustrating a photoelectric conversion device according to each embodiment.

FIG. 2 is a circuit diagram illustrating the photoelectric conversion device according to each embodiment.

FIG. 3 is a drive timing chart illustrating the photoelectric conversion device according to each embodiment.

FIGS. 4A, 4B, and 4C are plan views illustrating a photoelectric conversion device according to a first embodiment.

FIGS. 5A, 5B, and 5C are plan views illustrating a photoelectric conversion device according to a modification of the first embodiment.

FIGS. 6A, 6B, and 6C are plan views illustrating a photoelectric conversion device according to a second embodiment.

FIGS. 7A, 7B, and 7C are plan views illustrating a photoelectric conversion device according to a third embodiment.

FIGS. 8A, 8B, and 8C are plan views illustrating a photoelectric conversion device according to a fourth embodiment.

FIG. 9 is a circuit diagram illustrating a photoelectric conversion device according to a fifth embodiment.

FIGS. 10A, 10B, and 10C are plan views illustrating the photoelectric conversion device according to the fifth embodiment.

FIGS. 11A, 11B, and 11C are schematic diagrams illustrating equipment according to a sixth embodiment.

### DESCRIPTION OF THE EMBODIMENTS

Embodiments will now be described with reference to the drawings. It should be noted that the following embodiments do not limit the disclosure according to the claims. Although a plurality of features is described in the embodiments, not all of these features are essential to the disclosure, and the features may be arbitrarily combined. Furthermore, in the attached drawings, identical or similar configurations are given the same reference symbols, and overlapping descriptions are omitted. Also, in each of the embodiments described below, a sensor for imaging will be mainly described as an example of a photoelectric conversion device. Note that each embodiment is not limited to a sensor for imaging and is applicable to other examples of photoelectric conversion devices. For example, they include imaging devices, ranging devices (devices for focus detection and distance measurement using time of flight (TOF)), photometry devices (devices for measuring the incident light amount), and the like.

In the present specification, terms indicating a particular direction or position (such as “up”, “down”, “right”, “left”, and other terms including these terms) are used as needed. The use of these terms is for the purpose of facilitating the understanding of the embodiments with reference to the drawings, and the technical scope of the present disclosure is not limited by the meaning of these terms.

When it is described in the present specification as “member A and member B are electrically connected”, it is not limited to cases where member A and member B are directly connected. For example, even if another member C is connected between member A and member B, member A and member B are electrically connected as long as they are electrically connected.

In the present specification, “plane” refers to a plane in a direction parallel to the main surface of the substrate. The main surface of the substrate may be a light incident surface of the substrate including a photoelectric conversion element, a surface where a plurality of analog-to-digital converters (ADCs) are repeatedly disposed, or a junction surface between one substrate and another substrate in a multilayer photoelectric conversion device. Also, “plan view” refers to viewing from a direction perpendicular to the main surface of the substrate. Furthermore, “cross-section” refers to a plane in a direction perpendicular to the light incident surface of a semiconductor layer. Also, “cross-sectional view” refers to viewing from a direction parallel to the main surface of the substrate.

Metal members such as wiring and pads described in the present specification may be composed of a metal unit of one element or may be a mixture (alloy). For example, wiring described as copper wiring may be composed of a single piece of copper, or may be a configuration that mainly includes copper and further includes other components. Also, for example, a pad connected to an external terminal may be composed of a single piece of aluminum, or may be a configuration that mainly includes aluminum and further includes other components. The copper wiring and the aluminum pad described here are examples and can be modified to various metals. Moreover, the wiring and the pad described here are examples of metal members used in a photoelectric conversion device and can be applied to other metal members as well.

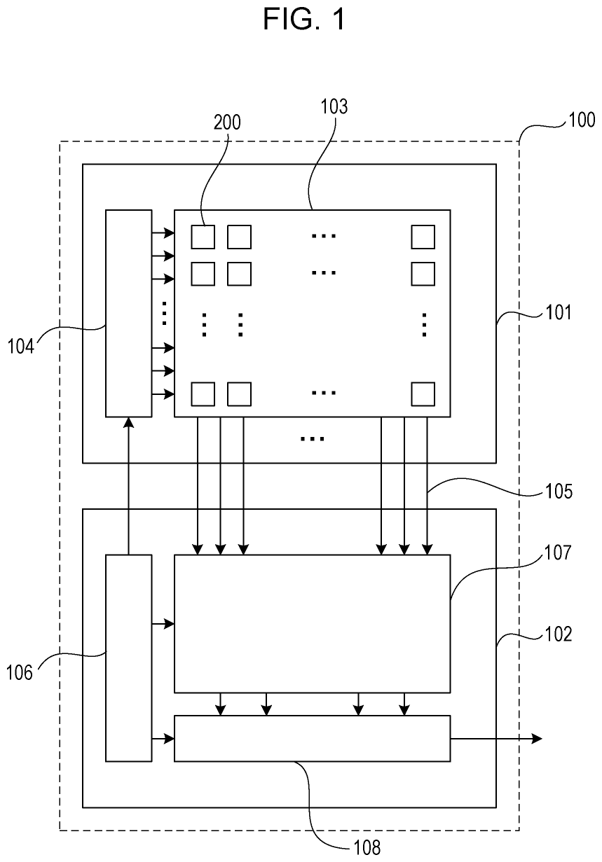

A configuration common to a photoelectric conversion device according to each embodiment of the present disclosure will be described using FIGS. 1 to 3.

FIG. 1 is a block diagram illustrating an example of a schematic configuration of a photoelectric conversion device applied to each embodiment.

As illustrated in FIG. 1, a photoelectric conversion device 100 includes a pixel substrate 101 and a circuit substrate 102. Here, the photoelectric conversion device 100 may be a configuration in which the circuit substrate 102 is stacked on a side opposite to the light incident surface of the pixel substrate 101. The pixel substrate 101 includes a pixel region 103 and a vertical scanning circuit 104. The circuit substrate 102 includes a timing generator (TG) unit 106, an analog-to-digital (AD) conversion unit 107, and an output unit 108. It should be noted that the photoelectric conversion device 100 may be a configuration in which components such as the pixel region 103 included in the pixel substrate 101 and components such as the TG unit 106 included in the circuit substrate 102 are provided on a single substrate.

The pixel region 103 includes a plurality of pixels 200 disposed in a two-dimensional manner including multiple rows and multiple columns. The vertical scanning circuit 104 supplies a plurality of control signals for controlling a plurality of transistors included in the pixels 200 to be on (conduction state) or off (non-conduction state). Each column of the pixels 200 is provided with first output lines 105, and signals from the pixels 200 are read out column by column to the first output lines 105.

The circuit substrate 102 includes a peripheral circuit that processes signals output by the first output lines 105. Note that the peripheral circuit at least includes the AD conversion unit 107. The AD conversion unit 107 converts analog signals output from the pixel region 103 via the first output lines 105 into digital signals. The output unit 108 outputs the digital signals output from the AD conversion unit 107 to the outside of the photoelectric conversion device 100. The TG unit 106 supplies control signals for controlling the vertical scanning circuit 104, the AD conversion unit 107, and the output unit 108 to the respective units.

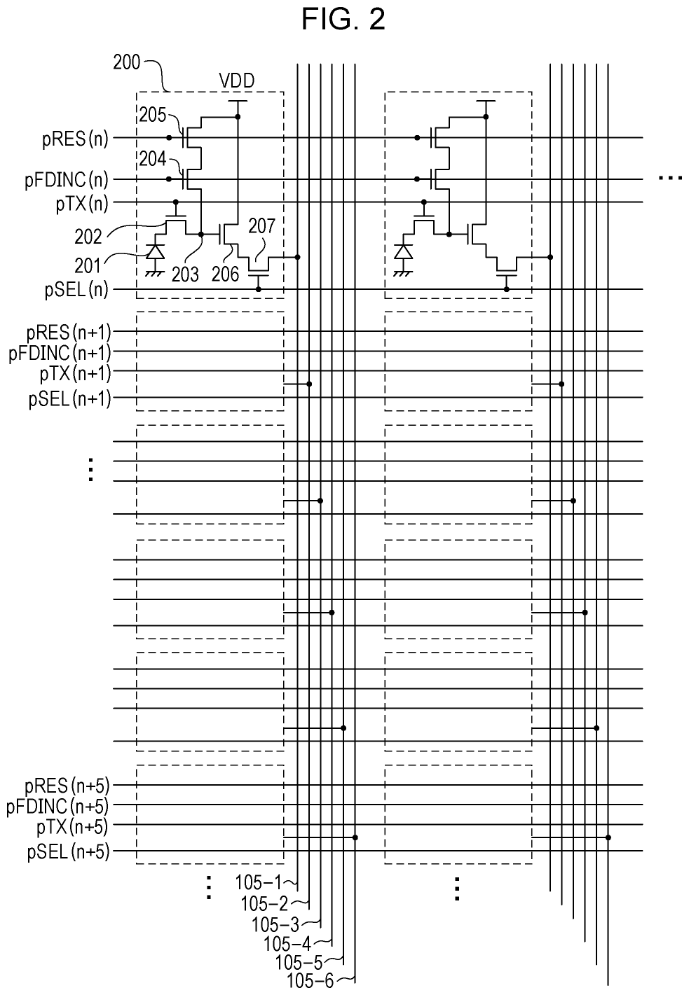

FIG. 2 is a circuit diagram illustrating an example of each pixel 200 included in the photoelectric conversion device applied to each embodiment. As illustrated in FIG. 2, one that includes a floating diffusion unit and a photoelectric conversion unit corresponding to the floating diffusion unit is defined as a pixel 200. Note that each pixel 200 may include multiple photoelectric conversion units. FIG. 2 illustrates a configuration in which a plurality of pixels 200 are disposed in a matrix, and, for each of columns where the pixels 200 are disposed, multiple first output lines 105 are disposed. FIG. 2 illustrates a configuration in which the pixels 200 are disposed in six rows and two columns as an example, but the number of pixels 200 is not limited thereto. Also, six first output lines 105-1 to 105-6 are provided for each column, but the number of first output lines 105 is not limited thereto. Hereinafter, in the present specification, a floating diffusion unit 203 may be written as an FD unit 203 (FD stands for floating diffusion).

As illustrated in FIG. 2, each pixel 200 includes a photoelectric conversion unit 201, a transfer transistor 202, and the FD unit 203. Each pixel 200 also includes a floating diffusion capacitance switching transistor 204 for switching the capacitance of the FD unit 203 as needed. Hereinafter, in the present specification, the floating diffusion capacitance switching transistor 204 may be written as the FD capacitance switching transistor 204. Each pixel 200 further includes a reset transistor 205 for resetting the FD unit 203, an amplifying transistor 206 for amplifying a signal, and a selection transistor 207. Also, the reset transistor 205 and the amplifying transistor 206 are supplied with a power supply voltage VDD. Note that the FD capacitance switching transistor 204 may not be disposed. Moreover, the selection transistor 207 may not be disposed.

The photoelectric conversion unit 201 is, for example, a photodiode. The photoelectric conversion unit 201 receives light incident on the pixel 200 and generates signal charge according to the incident light. The transfer transistor 202 is driven by a transfer transistor drive pulse pTX to transfer the signal charge generated in the photoelectric conversion unit 201 to the FD unit 203. The FD unit 203 functions as a charge-to-voltage conversion unit that temporarily holds the signal charge input from the photoelectric conversion unit 201 and simultaneously converts the held signal charge into a voltage signal. The FD capacitance switching transistor 204 is driven by an FD capacitance switching pulse pFDINC to switch the capacitance of the FD unit 203. By turning the FD capacitance switching transistor 204 on, capacitance equivalent to the gate capacitance of the FD capacitance switching transistor 204 can be added to the FD unit 203. The reset transistor 205 is driven by a reset transistor drive pulse pRES. At that time, the FD unit 203 can be reset by turning the reset transistor 205 and the FD capacitance switching transistor 204 on at the same time. The amplifying transistor 206 amplifies the signal converted by the FD unit 203. The selection transistor 207 is driven by a row selection drive pulse pSEL and outputs the amplified signal obtained by the amplifying transistor 206 to a corresponding one of the first output lines 105-1 to 105-6 on a pixel row by pixel row basis. That is, the selection transistor 207 selects the first output line 105 that outputs the amplified signal from among the plurality of first output lines 105-1 to 105-6. As a result, the first output line 105 outputs the signal according to the potential of the FD unit 203.

In order to distinguish between the first output lines 105, identification numbers (1, 2, 3, 4, . . . ) are added at the end of the reference symbols of the first output lines 105. Hereinafter, if it is necessary to distinguish between the first output lines 105, identification numbers are added at the end of the reference symbols of the components of the first output lines 105. However, if it is not necessary to distinguish between the first output lines 105, identification numbers at the end of the reference symbols of the components of the first output lines 105 are omitted. Furthermore, identification numbers (1, 2, 3, 4, . . . ) are similarly added to second output lines 405, which will be described later.

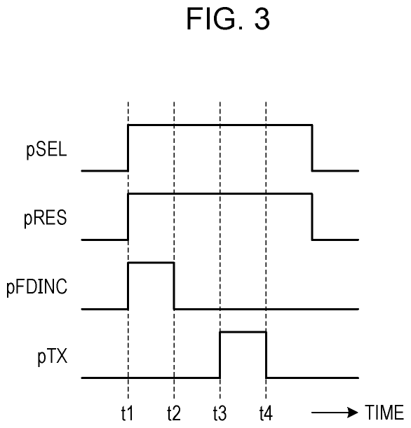

FIG. 3 is a timing chart illustrating an example of the drive of the photoelectric conversion device applied to each embodiment.

FIG. 3 is a timing chart when, at low luminance, the FD capacitance switching transistor 204 is turned off to output a signal. FIG. 3 has time on the horizontal axis and voltage on the vertical axis. Drive pulses illustrated in FIG. 3 correspond to those illustrated in FIG. 2.

At time t1, pFDINC, pRES, and pSEL are set to a high state. In doing so, the FD capacitance switching transistor 204, the reset transistor 205, and the selection transistor 207 are respectively turned on. As a result, the pixel 200 to be read out is selected, and the FD unit 203 is reset.

At time t2, the pFDINC is set to a low state. In doing so, the FD capacitance switching transistor 204 is turned off. As a result, the signal output to the first output line 105 through the amplifying transistor 206 at this time is output as a reset level signal. This reset level signal is converted by the AD conversion unit 107 into a digital signal. The drive described above can reduce the capacitance of the FD unit 203 during readout and reduce noise.

At time t3, pTX is set to a high state. In doing so, the transfer transistor 202 is turned on. As a result, the signal charge accumulated in the photoelectric conversion unit 201 is transferred to the FD unit 203.

At time t4, pTX is set to a low state. In doing so, the transfer transistor 202 is turned off. As a result, a signal according to the signal charge transferred to the FD unit 203 is output to the first output line 105 through the amplifying transistor 206. This signal is converted by the AD conversion unit 107 into a digital signal.

### First Embodiment

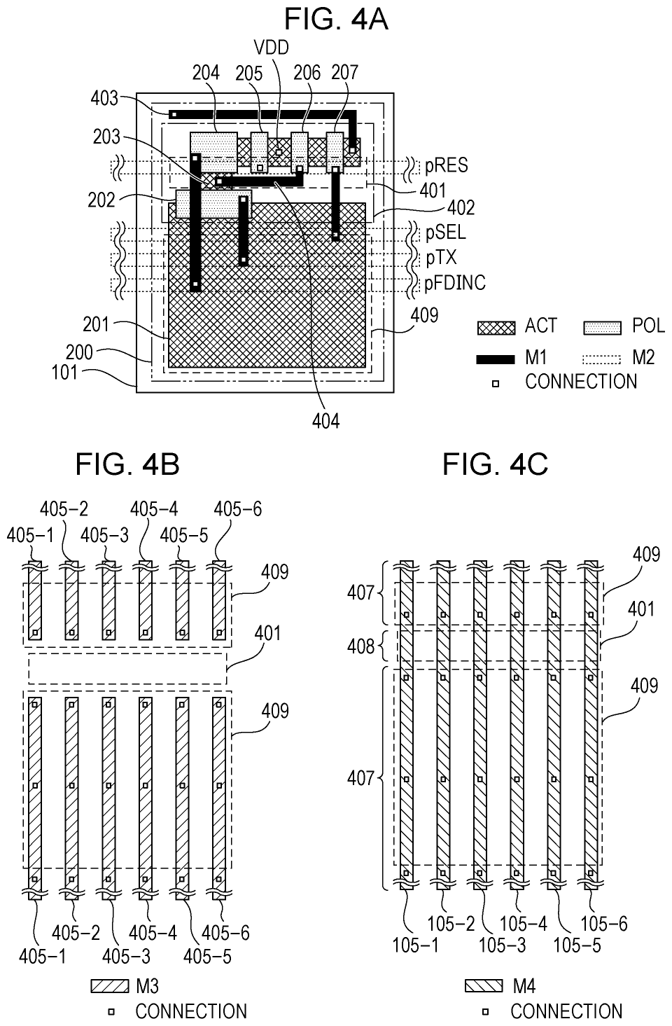

A photoelectric conversion device according to a first embodiment of the present disclosure will be described using FIGS. 4A, 4B, and 4C. It should be noted that components that are the same as or similar to those in FIGS. 1 to 3 are given the same reference symbols, and descriptions of these components may be omitted or simplified. In addition, the schematic configuration of the photoelectric conversion device according to the present embodiment is as described with reference to FIGS. 1 to 3.

Hereinafter, the photoelectric conversion device with the schematic configuration illustrated in FIGS. 1 to 3 will be described by focusing on points of view that are characteristic in the present embodiment.

FIGS. 4A, 4B, and 4C are plan views illustrating an example of the layout of each pixel 200 included in the photoelectric conversion device. Note that FIGS. 4A, 4B, and 4C illustrate a back-illuminated photoelectric conversion device in which a first wiring layer M1 is disposed on one of two sides of the pixel substrate 101, and light is incident on the photoelectric conversion unit 201 from the other side of the pixel substrate 101. That is, in FIGS. 4A, 4B, and 4C, light is incident on the photoelectric conversion unit 201 disposed on the pixel substrate 101 from the backside relative to the paper surface. Furthermore, the configuration may be one in which the circuit substrate 102 is stacked on one side of the pixel substrate 101. It should be noted that FIGS. 4A, 4B, and 4C omit, for the sake of simplicity of description, the layout of wiring for supplying the power supply voltage VDD and wiring for supplying a reference voltage. Also, FIGS. 4A, 4B, and 4C have the front side relative to the paper surface as the top side.

FIG. 4A illustrates a plan layout of an active region (ACT), polysilicon (POL), the first wiring layer M1, and a second wiring layer M2 of the pixel substrate 101. Note that polysilicon (POL) is provided on top of the active region (ACT) of the pixel substrate 101. Also, the first wiring layer M1 is provided on top of polysilicon (POL). Moreover, the second wiring layer M2 is provided on top of the first wiring layer M1. Note that the first wiring layer M1 has first wiring 403 and second wiring 404.

A region where the transfer transistor 202, the FD unit 203, the reset transistor 205, and the amplifying transistor 206 are disposed serves as a pixel transistor region 402. In addition, the FD capacitance switching transistor 204 and the selection transistor 207 are disposed in the pixel transistor region 402. Note that the FD capacitance switching transistor 204 and the selection transistor 207 may not be disposed in the pixel transistor region 402. In the present embodiment, within a single pixel 200, the photoelectric conversion unit 201 and the pixel transistor region 402 are disposed in a column direction.

The gate of each transistor is connected to a corresponding one of drive control lines that output pRES, pSEL, pTX, and pFDINC via the first wiring layer M1. Note that the above-described drive control lines are included in the second wiring layer M2. The source or drain of the selection transistor 207 is connected to either a corresponding one of the first output lines 105 or the second output lines 405, which will be described later, via the first wiring 403. Note that the second output lines 405 and the first output lines 105 are respectively disposed in a third wiring layer M3 and a fourth wiring layer M4, which will be described later.

In a plan view relative to the main surface of the pixel substrate 101, a region in which the first output lines 105 overlap with at least a portion of the pixel transistor region 402 serves as a first region 401. Note that the first region 401 may include, in a plan view relative to the main surface of the pixel substrate 101, a region between the multiple first output lines 105 that overlaps with at least a portion of the pixel transistor region 402. In the present embodiment, in a plan view relative to the main surface of the pixel substrate 101, the FD unit 203 and the second wiring 404 connecting the FD unit 203 and the gate of the amplifying transistor 206 are positioned to overlap with at least a portion of the first region 401. Also, in a plan view relative to the main surface of the pixel substrate 101, a region outside the first region 401, in which the second output lines 405 overlap with at least a portion of the photoelectric conversion unit 201, serves as a second region 409. Note that the second region 409 may include, in a plan view relative to the main surface of the pixel substrate 101, a region between the multiple second output lines 405 that overlaps with at least a portion of the photoelectric conversion unit 201. Also, in a plan view relative to the main surface of the pixel substrate 101, the first region 401 and the second region 409 are regions included in one pixel 200.

FIG. 4B illustrates a plan layout of the third wiring layer M3. Note that the third wiring layer M3 is provided on top of the second wiring layer M2. Also, in FIG. 4B, taking into consideration the second region 409 included in each of pixels 200 that are adjacent to one another in a column direction, the first region 401 is present between multiple second regions 409 in a plan view relative to the main surface of the pixel substrate 101.

The third wiring layer M3 is provided with second output lines 405-1 to 405-6. The second output lines 405-1 to 405-6 are electrically connected to the first output lines 105-1 to 105-6, respectively, which will be described later, via connections. The connections are, for example, vias. Note that the first output lines 105 are included in the fourth wiring layer M4 provided on top of the third wiring layer M3. That is, in a cross-sectional view relative to the main surface of the pixel substrate 101, the second output lines 405 are disposed between the first output lines 105 and the photoelectric conversion unit 201. Furthermore, in a plan view relative to the main surface of the pixel substrate 101, the second output lines 405-1 to 405-6 are positioned to overlap with at least a portion of the first output lines 105-1-105-6.

However, in a plan view relative to the main surface of the pixel substrate 101, the second output lines 405 are positioned not to overlap with the first region 401. That is, in a plan view relative to the main surface of the pixel substrate 101, the second output lines 405 are positioned not to overlap with the FD unit 203. Also, in a plan view relative to the main surface of the pixel substrate 101, the second output lines 405 are positioned not to overlap with the second wiring 404 connecting the FD unit 203 and the gate of the amplifying transistor 206. Thus, in a plan view relative to the main surface of the pixel substrate 101, an end portion of each of the second output lines 405-1 to 405-6 intersecting with respect to the longer-side direction of the second output lines 405-1 to 405-6 is positioned to overlap with at least a portion of the second region 409. Note that both end portions of each of the second output lines 405-1 to 405-6 intersecting with respect to the longer-side direction of the second output lines 405-1 to 405-6 may be positioned to overlap with at least a portion of the second region 409.

In a plan view relative to the main surface of the pixel substrate 101, in the case where the second output lines 405 are positioned to overlap with at least a portion of the first region 401, parasitic capacitance occurs between the second output lines 405 and the FD unit 203. Parasitic capacitance also occurs between the second output lines 405 and the second wiring 404. In the case where parasitic capacitance occurs between the second output lines 405 and the FD unit 203, fluctuations when signals are output to the second output lines 405 are transmitted to the FD unit 203, and the voltage level of the FD unit 203 fluctuates. As a result, crosstalk occurs between signals from multiple pixels 200 that are read out in parallel. Also, in the case where parasitic capacitance occurs between the second output lines 405 and the second wiring 404, crosstalk similarly occurs. However, the occurrence of parasitic capacitance between the second output lines 405 and the FD portion 203 can be suppressed by not positioning the second output lines 405 to overlap with at least a portion of the first region 401 in a plan view relative to the main surface of the pixel substrate 101. Furthermore, the occurrence of parasitic capacitance between the second output lines 405 and the second wiring 404 can also be suppressed. Thus, the configuration of the present embodiment can suppress crosstalk.

FIG. 4C illustrates a plan layout of the fourth wiring layer M4. Note that the fourth wiring layer M4 is provided on top of the third wiring layer M3.

The fourth wiring layer M4 is provided with the first output lines 105-1 to 105-6. In a plan view relative to the main surface of the pixel substrate 101, the first output lines 105 are positioned to overlap with at least a portion of the FD unit 203. Also, in a plan view relative to the main surface of the pixel substrate 101, the first output lines 105 are positioned to overlap with at least a portion of the second wiring 404 connecting the FD unit 203 and the gate of the amplifying transistor 206. Here, portions of the first output lines 105 positioned to overlap with at least a portion of the second region 409 in a plan view relative to the main surface of the pixel substrate 101 are defined as backing wiring portions 407. Also, portions of the first output lines 105 positioned to overlap with at least a portion of the first region 401 in a plan view relative to the main surface of the pixel substrate 101 are defined as non-backing wiring portions 408.

In the backing wiring portions 407, the first output lines 105-1 to 105-6 are electrically connected to the second output lines 405-1 to 405-6, respectively, via connections. The connections are, for example, vias. By interconnecting the output lines included in two wiring layers, the output lines are each composed of two wiring layers. For example, by connecting the first output line 105-1 and the second output line 405-1 to each other, these output lines are composed of output lines provided in two wiring layers. In contrast, in the non-backing wiring portions 408, the first output lines 105-1 to 105-6 are not electrically connected to the second output lines 405-1 to 405-6.

In the manufacturing process, if a break occurs in any output line, a signal from a pixel connected to the broken output line will not be correctly output. Therefore, this photoelectric conversion device becomes defective. However, in the configuration of the present embodiment, in an output line composed of two wiring layers, even if a break occurs in one wiring layer, the output line can output a signal through the other wiring layer. Therefore, the probability of a manufacturing defect occurring such that a signal from a pixel is not accurately output can be reduced. Thus, a decrease in the production yield can be suppressed. Note that an output line where a break occurs in one of two wiring layers has increased impedance since the output line only has a single wiring layer. However, if the number of connections connecting the two wiring layers is large, the impact of this impedance increase on the overall impedance of the output lines is negligibly small.

As illustrated in FIGS. 4A, 4B, and 4C, because the second output lines 405 are not provided at positions that overlap with at least a portion of the first region 401 in a plan view relative to the main surface of the pixel substrate 101, close proximity between the FD unit 203 and the second output lines 405 can be prevented. This configuration can suppress the occurrence of crosstalk due to an increase in the parasitic capacitance between the FD unit 203 and the second output lines 405. This configuration can also suppress the occurrence of crosstalk likewise due to an increase in the parasitic capacitance between the second wiring 404 and the second output lines 405.

In the meantime, by providing the second output lines 405, electrically connected to the first output lines 105, at positions that overlap with at least a portion of the second region 409 in a plan view relative to the main surface of the pixel substrate 101, the output lines are configured as two layers of the third wiring layer M3 and the fourth wiring layer M4. This configuration can reduce the probability of a manufacturing defect occurring that a signal from a pixel will not be output correctly due to a break in any output line during the manufacturing process. As a result, the yield can be improved.

Accordingly, the present embodiment enables both yield improvement and crosstalk suppression by providing the backing wiring portions 407 and the non-backing wiring portions 408 in the first output lines 105.

Note that, in the present embodiment, the positional relationship between the third wiring layer M3 where the second output lines 405 are disposed and the fourth wiring layer M4 where the first output lines 105 are disposed may be reversed. That is, the configuration may be such that the third wiring layer M3 illustrated in FIG. 4B is disposed above the fourth wiring layer M4 illustrated in FIG. 4C. Even with such a configuration, in a plan view relative to the main surface of the pixel substrate 101, the second output lines 405 are not positioned to overlap with at least a portion of the first region 401. Therefore, in a plan view relative to the main surface of the pixel substrate 101, crosstalk is suppressed compared to the case where the second output lines 405 are positioned to overlap with at least a portion of the first region 401.

Note that the present embodiment may be a front-illuminated photoelectric conversion device in which the first wiring layer M1 is disposed on one side of the pixel substrate 101 and light is incident on the photoelectric conversion unit 201 from one side of the pixel substrate 101. In that case, in FIGS. 4A, 4B, and 4C, light is incident on the photoelectric conversion unit 201 disposed on the pixel substrate 101 from the front side relative to the paper surface.

Although the output lines are the first output lines 105 and the second output lines 405 composed of two layers in the present embodiment, the output lines may be composed of three or more layers.

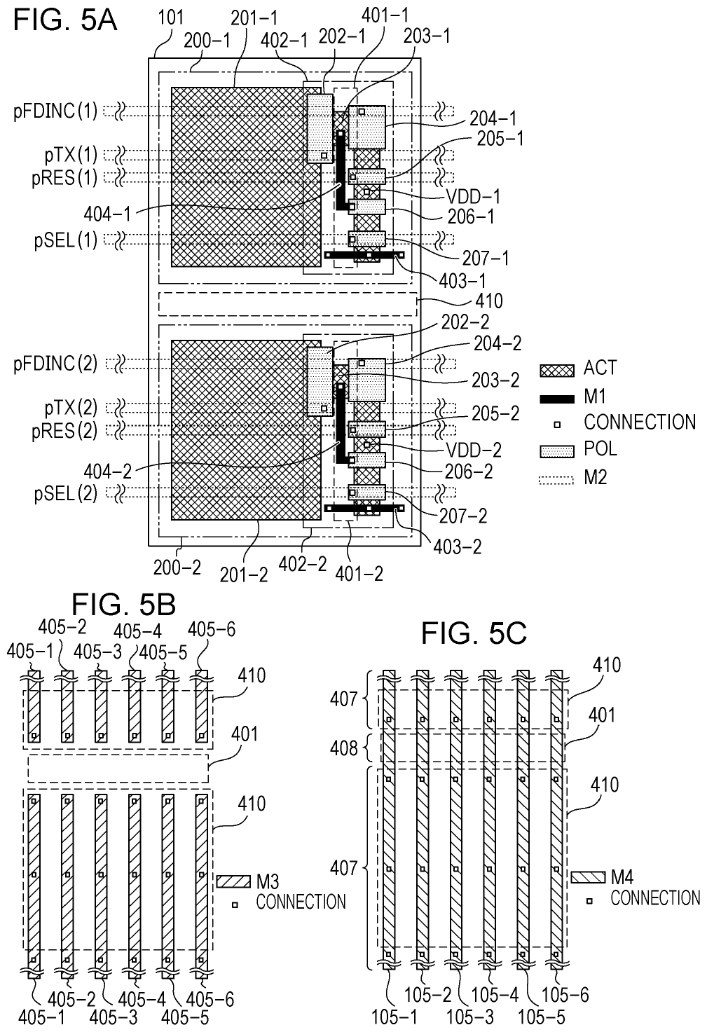

A photoelectric conversion device according to a modification of the first embodiment of the present disclosure will be described using FIGS. 5A, 5B, and 5C. It should be noted that components that are the same as or similar to those of the first embodiment are given the same reference symbols, and descriptions of these components may be omitted or simplified.

The modification of the first embodiment is different from the first embodiment in the arrangement of the photoelectric conversion unit 201 and the pixel transistor region 402 included in each pixel 200. FIGS. 5A, 5B, and 5C are plan views illustrating an example of the layout of each pixel 200 included in the photoelectric conversion device. Note that the pixels 200 illustrated in FIGS. 5A, 5B, and 5C have common components. Therefore, identification numbers (1, 2, 3, 4, . . . ) are added at the end of the reference symbols of the components of the pixels 200 in order to distinguish between the components of the pixels 200. Hereinafter, if it is necessary to distinguish between the components of the pixels 200, identification numbers are added at the end of the reference symbols of the components of the pixels 200. However, if it is not necessary to distinguish between the components of the pixels 200, identification numbers at the end of the reference symbols of the components of the pixels 200 are omitted.

As illustrated in FIG. 5A, a first pixel 200-1 and a second pixel 200-2 are disposed next to each other in a column direction. The first pixel 200-1 includes a first photoelectric conversion unit 201-1 and a first pixel transistor region 402-1. In the meantime, the second pixel 200-2 includes a second photoelectric conversion unit 201-2 and a second pixel transistor region 402-2. Note that the pixel transistor region 402 is a region where the transfer transistor 202, the FD unit 203, the reset transistor 205, and the amplifying transistor 206 are disposed. Also, within a single pixel 200, the photoelectric conversion unit 201 and the pixel transistor region 402 are disposed in a row direction.

The gate of each transistor is connected to a corresponding one of drive control lines that output pRES, pSEL, pTX, and pFDINC. Note that the above-described drive control lines are included in the second wiring layer M2.

The source or drain of the selection transistor 207 is connected to either a corresponding one of the first output lines 105 or the second output lines 405, which will be described later, via the first wiring 403.

In a plan view relative to the main surface of the pixel substrate 101, the region in which the first output lines 105 overlap with at least a portion of the pixel transistor region 402 serves as the first region 401. Note that the first region 401 may include, in a plan view relative to the main surface of the pixel substrate 101, a region between the multiple first output lines 105 that overlaps with at least a portion of the pixel transistor region 402. In addition, in a plan view relative to the main surface of the pixel substrate 101, a region outside the first region 401 and present between the first pixel transistor region 402-1 and the second pixel transistor region 402-2 serves as a third region 410.

FIG. 5B illustrates a plan layout of the third wiring layer M3. Note that the third wiring layer M3 is provided on top of the second wiring layer M2. The third wiring layer M3 is provided with the second output lines 405-1 to 405-6. Also, in FIG. 5B, taking into consideration the third region 410 disposed between multiple pixels 200 adjacent to each other in a column direction, the first region 401 is present between multiple third regions 410 in a plan view relative to the main surface of the pixel substrate 101. Note that the first pixel 200-1 and the second pixel 200-2 are disposed next to each other in the longer-side direction of the second output lines 405.

In a plan view relative to the main surface of the pixel substrate 101, the second output lines 405 are positioned not to overlap with the first region 401. That is, in a plan view relative to the main surface of the pixel substrate 101, the second output lines 405 are positioned not to overlap with the FD unit 203. Also, in a plan view relative to the main surface of the pixel substrate 101, the second output lines 405 are positioned not to overlap with the second wiring 404 connecting the FD unit 203 and the gate of the amplifying transistor 206. Thus, in a plan view relative to the main surface of the pixel substrate 101, an end portion of each of the second output lines 405-1 to 405-6 intersecting with respect to the longer-side direction of the second output lines 405-1 to 405-6 is positioned to overlap with at least a portion of the third region 410. Note that both end portions of each of the second output lines 405-1 to 405-6 intersecting with respect to the longer-side direction of the second output lines 405-1 to 405-6 may be positioned to overlap with at least a portion of the third region 410.

FIG. 5C illustrates a plan layout of the fourth wiring layer M4. Note that the fourth wiring layer M4 is provided on top of the third wiring layer M3. The fourth wiring layer M4 is provided with the first output lines 105-1 to 105-6. The first output lines 105-1 to 105-6 are electrically connected to the second output lines 405-1 to 405-6, respectively. Here, portions of the first output lines 105 positioned to overlap with at least a portion of the third region 410 in a plan view relative to the main surface of the pixel substrate 101 are defined as the backing wiring portions 407. Also, portions of the first output lines 105 positioned to overlap with at least a portion of the first region 401 in a plan view relative to the main surface of the pixel substrate 101 are defined as the non-backing wiring portions 408.

As illustrated in FIGS. 5A, 5B, and 5C, because the second output lines 405 are not provided at positions that overlap with at least a portion of the first region 401 in a plan view relative to the main surface of the pixel substrate 101, close proximity between the FD unit 203 and the second output lines 405 can be prevented. This configuration can suppress the occurrence of crosstalk due to an increase in the parasitic capacitance between the FD unit 203 and the second output lines 405. Likewise, this configuration can also suppress the occurrence of crosstalk due to an increase in the parasitic capacitance between the second wiring 404 and the second output lines 405.

In the meantime, by providing the second output lines 405, electrically connected to the first output lines 105, at positions that overlap with at least a portion of the third region 410 in a plan view relative to the main surface of the pixel substrate 101, the output lines are configured as two layers of the third wiring layer M3 and the fourth wiring layer M4. This configuration can reduce the probability of a manufacturing defect occurring that a signal from a pixel will not be output correctly due to a break in any output line during the manufacturing process. As a result, the yield can be improved.

Accordingly, the present embodiment enables both yield improvement and crosstalk suppression by providing the backing wiring portions 407 and the non-backing wiring portions 408 in the first output lines 105.

### Second Embodiment

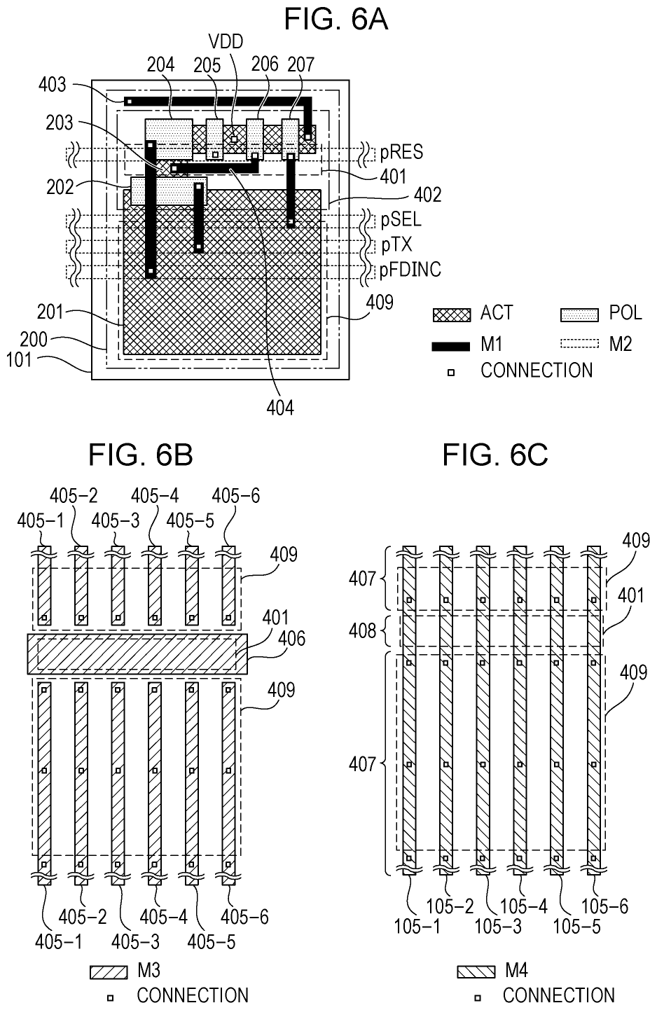

A photoelectric conversion device according to a second embodiment of the present disclosure will be described using FIGS. 6A, 6B, and 6C. It should be noted that components that are the same as or similar to those of the first embodiment are given the same reference symbols, and descriptions of these components may be omitted or simplified.

The present embodiment is different from the first embodiment in that shield wiring 406 is provided in the third wiring layer M3. FIGS. 6A, 6B, and 6C are plan views illustrating an example of the layout of each pixel 200 included in the photoelectric conversion device. Note that FIG. 6A is the same as FIG. 4A illustrating the first embodiment.

FIG. 6B illustrates a plan layout of the third wiring layer M3 corresponding to FIG. 4B illustrating the first embodiment. As illustrated in FIG. 6B, the third wiring layer M3 is provided with the shield wiring 406. Also, in a plan view relative to the main surface of the pixel substrate 101, the shield wiring 406 is positioned to overlap with at least a portion of the first region 401. That is, in a plan view relative to the main surface of the pixel substrate 101, not only the second output line 405 are not positioned to overlap with at least a portion of the first region 401, but also the shield wiring 406 is positioned to overlap with at least a portion of the first region 401. Furthermore, the shield wiring 406 is set to the reference voltage or the power supply voltage VDD.

FIG. 6C illustrates a plan layout of the fourth wiring layer M4 corresponding to FIG. 4C illustrating the first embodiment. As illustrated in FIGS. 6A, 6B, and 6C, in a cross-sectional view relative to the main surface of the pixel substrate 101, the shield wiring 406 is disposed between the first output lines 105 and the pixel transistor region 402.

Accordingly, the present embodiment enables both yield improvement and crosstalk suppression by providing the backing wiring portions 407 and the non-backing wiring portions 408 in the first output lines 105. Furthermore, in the present embodiment, the above configuration can not only suppress crosstalk caused by the second output lines 405, but also suppress crosstalk caused by the first output lines 105. That is, the occurrence of parasitic capacitance between the FD unit 203 disposed beneath the shield wiring 406 and the first output lines 105 disposed above the shield wiring 406 can be suppressed. In addition, the occurrence of parasitic capacitance between the second wiring 404 disposed beneath the shield wiring 406 and the first output lines 105 disposed above the shield wiring 406 can also be suppressed. Furthermore, by providing the shield wiring 406 in a region where the second output lines 405 in the third wiring layer M3 are not provided, it becomes unnecessary to newly provide a wiring layer for the shield wiring 406. For example, it is not necessary to newly provide a wiring layer between the third wiring layer M3 and the fourth wiring layer M4. Therefore, an increase in manufacturing costs can be suppressed.

### Third Embodiment

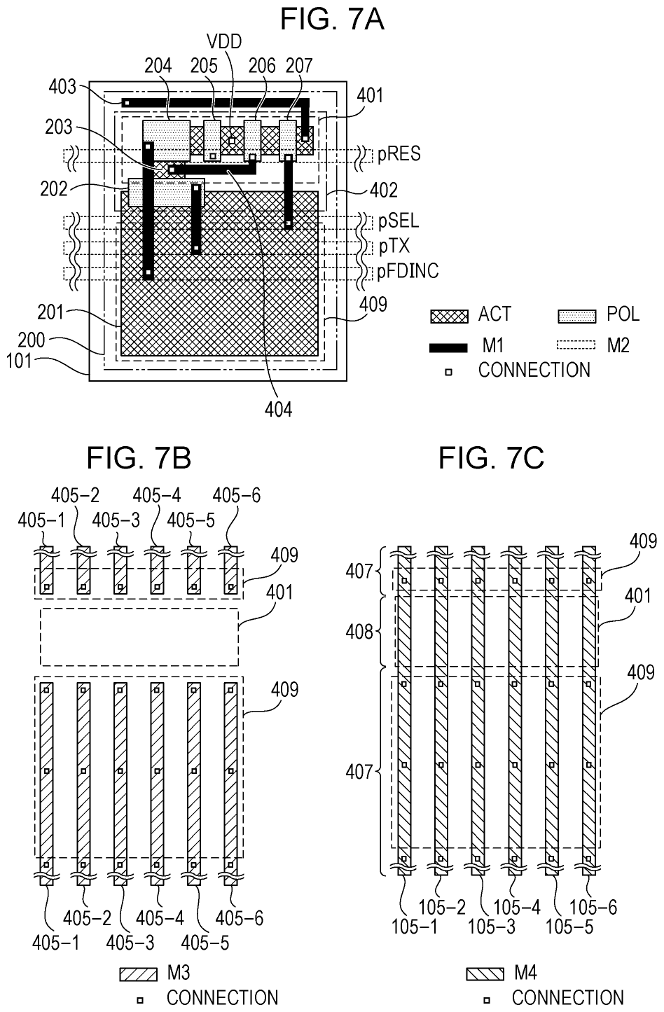

A photoelectric conversion device according to a third embodiment of the present disclosure will be described using FIGS. 7A, 7B, and 7C. It should be noted that components that are the same as or similar to those of the first embodiment and the second embodiment are given the same reference symbols, and descriptions of these components may be omitted or simplified.

The present embodiment is different from the first embodiment and the second embodiment in the size of the range of the first region 401. FIGS. 7A, 7B, and 7C are plan views illustrating an example of the layout of each pixel 200 included in the photoelectric conversion device.

As illustrated in FIG. 7A, in a plan view relative to the main surface of the pixel substrate 101, a region including the FD unit 203 and a node connected to the FD unit 203 is positioned to overlap with at least a portion of the first region 401. The region including the node connected to the FD unit 203 includes the gate of the amplifying transistor 206 and the FD capacitance switching transistor 204. Furthermore, the region including the node connected to the FD unit 203 includes the second wiring 404 connecting the FD unit 203 and the gate of the amplifying transistor 206. Note that, in a plan view relative to the main surface of the pixel substrate 101, the amplifying transistor 206, the reset transistor 205, and the selection transistor 207 may be positioned to overlap with at least a portion of the first region 401.

FIG. 7B illustrates a plan layout of the third wiring layer M3. Note that the third wiring layer M3 is provided on top of the second wiring layer M2. The third wiring layer M3 is provided with the second output lines 405-1 to 405-6. In a plan view relative to the main surface of the pixel substrate 101, the second output lines 405 are positioned not to overlap with the first region 401. That is, in a plan view relative to the main surface of the pixel substrate 101, the second output lines 405 are positioned not to overlap with the FD unit 203. Also, in a plan view relative to the main surface of the pixel substrate 101, the second output lines 405 are positioned not to overlap with the region including the node connected to the FD unit 203. Thus, in a plan view relative to the main surface of the pixel substrate 101, an end portion of each of the second output lines 405-1 to 405-6 intersecting with respect to the longer-side direction of the second output lines 405-1 to 405-6 is positioned to overlap with at least a portion of the second region 409.

In a plan view relative to the main surface of the pixel substrate 101, in the case where the second output lines 405 are positioned to overlap with at least a portion of the first region 401, parasitic capacitance occurs between the second output lines 405 and the FD unit 203. Parasitic capacitance also occurs between the second output lines 405 and the region including the node connected to the FD unit 203. In the case where parasitic capacitance occurs between the second output lines 405 and the FD unit 203, fluctuations when a signal is output to a corresponding one of the second output lines 405 are transmitted to the FD unit 203, and the voltage level of the FD unit 203 fluctuates. As a result, crosstalk occurs between signals from multiple pixels 200 that are read out in parallel. Also, in the case where parasitic capacitance occurs between the second output lines 405 and the second wiring 404, crosstalk similarly occurs. However, the occurrence of parasitic capacitance between the second output lines 405 and the FD portion 203 can be suppressed by not positioning the second output lines 405 to overlap with at least a portion of the first region 401 in a plan view relative to the main surface of the pixel substrate 101. Furthermore, the occurrence of parasitic capacitance between the second output lines 405 and the region including the node connected to the FD unit 203 can also be suppressed. Thus, the configuration of the present embodiment can suppress crosstalk.

FIG. 7C illustrates a plan layout of the fourth wiring layer M4. Note that the fourth wiring layer M4 is provided on top of the third wiring layer M3. The fourth wiring layer M4 is provided with the first output lines 105-1 to 105-6. In a plan view relative to the main surface of the pixel substrate 101, the first output lines 105 are positioned to overlap with at least a portion of the FD unit 203. Also, in a plan view relative to the main surface of the pixel substrate 101, the first output lines 105 are positioned to overlap with at least a portion of the region including the node connected to the FD unit 203. Here, portions of the first output lines 105 positioned to overlap with at least a portion of the second region 409 in a plan view relative to the main surface of the pixel substrate 101 are defined as the backing wiring portions 407. Also, portions of the first output lines 105 positioned to overlap with at least a portion of the first region 401 in a plan view relative to the main surface of the pixel substrate 101 are defined as the non-backing wiring portions 408.

As illustrated in FIGS. 7A, 7B, and 7C, because the second output lines 405 are not provided at positions that overlap with at least a portion of the first region 401 in a plan view relative to the main surface of the pixel substrate 101, close proximity between the FD unit 203 and the second output lines 405 can be prevented. This configuration can suppress the occurrence of crosstalk due to an increase in the parasitic capacitance between the FD unit 203 and the second output lines 405. Likewise, this configuration can also suppress the occurrence of crosstalk due to an increase in the parasitic capacitance between the region including the node connected to the FD unit 203 and the second output lines 405.

In the meantime, by providing the second output lines 405, electrically connected to the first output lines 105, at positions that overlap with at least a portion of the second region 409 in a plan view relative to the main surface of the pixel substrate 101, the output lines are configured as two layers of the third wiring layer M3 and the fourth wiring layer M4. This configuration can reduce the probability of a manufacturing defect occurring that a signal from a pixel will not be output correctly due to a break in any output line during the manufacturing process. As a result, the yield can be improved.

Accordingly, the present embodiment enables both yield improvement and crosstalk suppression by providing the backing wiring portions 407 and the non-backing wiring portions 408 in the first output lines 105. Furthermore, the present embodiment sets the first region 401 to a wider range as compared to the first embodiment and the second embodiment. As a result, the region where the second output lines 405 are not disposed becomes larger, and an increase in the parasitic capacitance caused by the second output lines 405 can be suppressed in a wider range. Thus, the present embodiments can more effectively suppress crosstalk.

### Fourth Embodiment

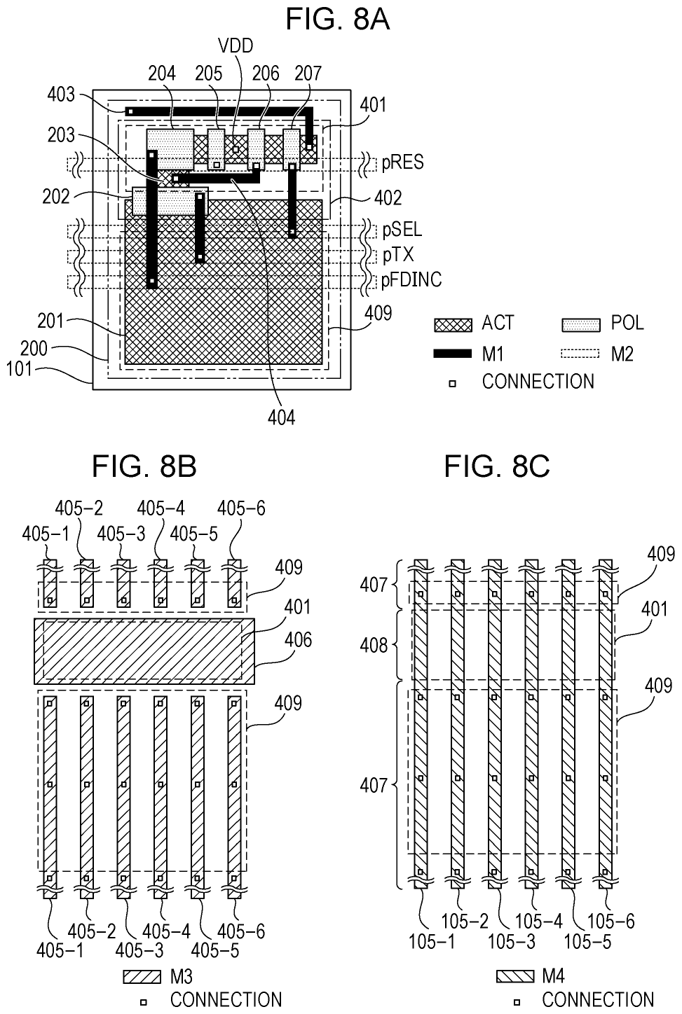

A photoelectric conversion device according to a fourth embodiment of the present disclosure will be described using FIGS. 8A, 8B, and 8C. It should be noted that components that are the same as or similar to those of the first embodiment, the second embodiment, and the third embodiment are given the same reference symbols, and descriptions of these components may be omitted or simplified.

The present embodiment is a configuration obtained by applying the configuration of the second embodiment to the third embodiment. FIGS. 8A, 8B, and 8C are plan views illustrating an example of the layout of each pixel 200 included in the photoelectric conversion device.

Note that FIG. 8A is the same as FIG. 7A illustrating the third embodiment.

FIG. 8B illustrates a plan layout of the third wiring layer M3 corresponding to FIG. 7B illustrating the third embodiment. As illustrated in FIG. 8B, the third wiring layer M3 is provided with the shield wiring 406. Also, in a plan view relative to the main surface of the pixel substrate 101, the shield wiring 406 is positioned to overlap with at least a portion of the first region 401. That is, the configuration is such that not only the second output lines 405 are not positioned to overlap the first region 401 in a plan view relative to the main surface of the pixel substrate 101 but also the shield wiring 406 is positioned to overlap with at least a portion of the first region 401. Furthermore, the shield wiring 406 is set to the reference voltage or the power supply voltage VDD.

FIG. 8C illustrates a plan layout of the fourth wiring layer M4 corresponding to FIG. 7C illustrating the third embodiment. As illustrated in FIGS. 8A, 8B, and 8C, in a cross-sectional view relative to the main surface of the pixel substrate 101, the shield wiring 406 is disposed between the first output lines 105 and the pixel transistor region 402.

Accordingly, the present embodiment enables both yield improvement and crosstalk suppression by providing the backing wiring portions 407 and the non-backing wiring portions 408 in the first output lines 105. Furthermore, in the present embodiment, the above configuration can not only suppress crosstalk caused by the second output lines 405, but also suppress crosstalk caused by the first output lines 105. That is, the occurrence of parasitic capacitance between the FD unit 203 disposed beneath the shield wiring 406 and the first output lines 105 disposed above the shield wiring 406 can be suppressed. In addition, the occurrence of parasitic capacitance between the second wiring 404 disposed beneath the shield wiring 406 and the first output lines 105 disposed above the shield wiring 406 can also be suppressed. Furthermore, by providing the shield wiring 406 in a region where the second output lines 405 in the third wiring layer M3 are not provided, it becomes unnecessary to newly provide a wiring layer for the shield wiring 406. For example, it is not necessary to newly provide a wiring layer between the third wiring layer M3 and the fourth wiring layer M4. Therefore, an increase in manufacturing costs can be suppressed.

### Fifth Embodiment

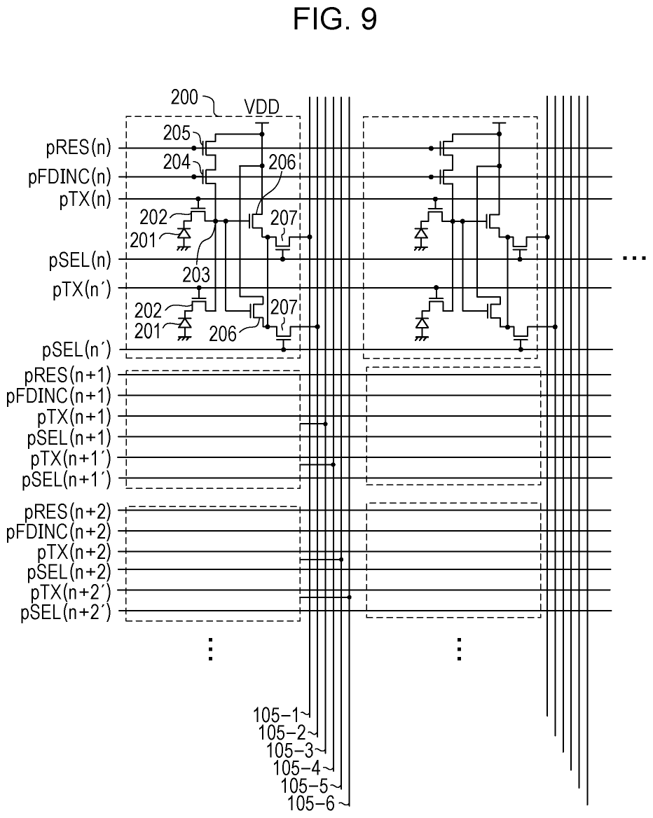

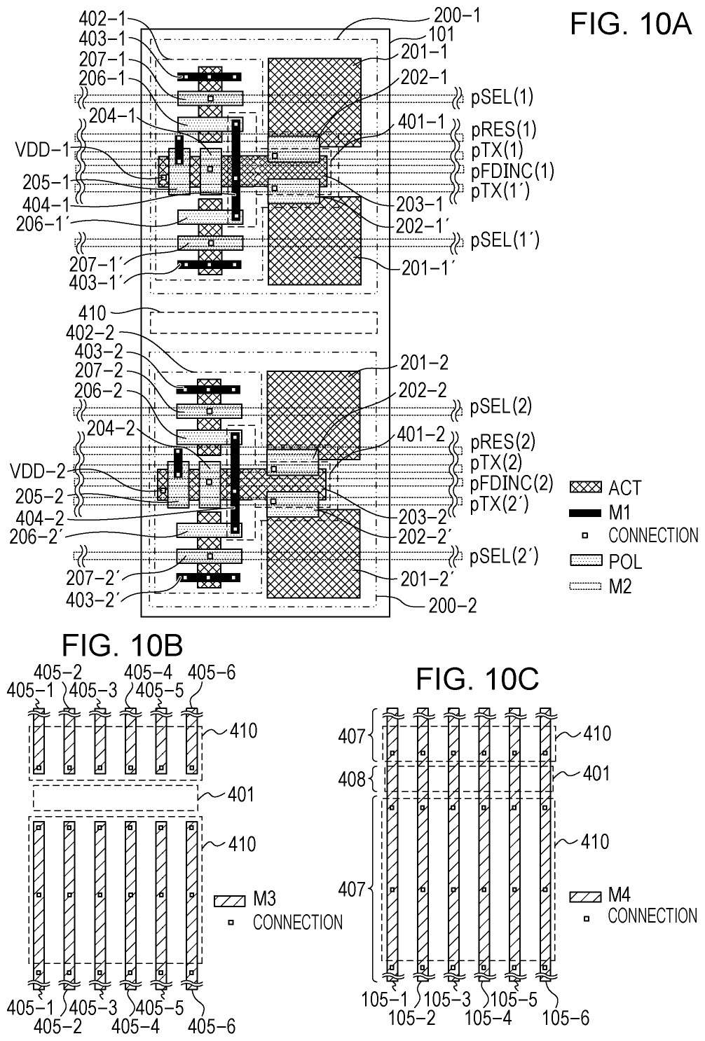

A photoelectric conversion device according to a fifth embodiment of the present disclosure will be described using FIGS. 9, 10A, 10B, and 10C. It should be noted that components that are the same as or similar to those of the first embodiment, the second embodiment, the third embodiment, and the fourth embodiment are given the same reference symbols, and descriptions of these components may be omitted or simplified.

The present embodiment is different from the first embodiment in that a plurality of photoelectric conversion units share at least one of the FD unit and wiring connecting the FD unit and the gate of the amplifying transistor. FIG. 9 is a circuit diagram illustrating an example of each pixel 200 included in the photoelectric conversion device. In the present embodiment, as illustrated in FIG. 9, one that includes an FD unit and a plurality of photoelectric conversion units corresponding to the FD unit is defined as a pixel 200. It should be noted that one that includes a piece of wiring connecting the FD unit and the gate of the amplifying transistor and a plurality of photoelectric conversion units corresponding to the piece of wiring connecting the FD unit and the gate of the amplifying transistor may be defined as a pixel 200. FIG. 9 illustrates a configuration in which a plurality of pixels 200 are disposed in a matrix, and, for each of columns where the pixels 200 are disposed, multiple first output lines 105 are disposed. FIG. 9 illustrates a configuration in which the pixels 200 are disposed in three rows and two columns as an example, but the number of pixels 200 is not limited thereto. Also, six first output lines 105-1 to 105-6 are provided for each column, but the number of first output lines 105 is not limited thereto. Note that a plurality of common components is disposed corresponding to one pixel 200. Thus, a prime (′) is added at the end of the reference symbols of the components corresponding to one pixel 200 in order to distinguish between the components corresponding to one pixel 200. Hereinafter, if it is necessary to distinguish between the components corresponding to one pixel 200, a prime is added at the end of the reference symbols of the components corresponding to one pixel 200. However, if it is not necessary to distinguish between the components corresponding to one pixel 200, a prime at the end of the reference symbols of the components of corresponding to one pixel 200 is omitted.

As illustrated in FIG. 9, each pixel 200 includes a plurality of photoelectric conversion units 201, a plurality of transfer transistors 202, and the FD unit 203. Each pixel 200 also includes the FD capacitance switching transistor 204 for switching the capacitance of the FD unit 203 as needed. Furthermore, each pixel 200 includes the reset transistor 205 for resetting the FD unit 203, a plurality of amplifying transistors 206 for amplifying signals, and a plurality of selection transistors 207. Also, the reset transistor 205 and the plurality of amplifying transistors 206 are supplied with the power supply voltage VDD. In the present embodiment, the plurality of photoelectric conversion units 201 included in each pixel 200 share the FD unit 203, the FD capacitance switching transistor 204, and the reset transistor 205. Note that the FD capacitance switching transistor 204 may not be disposed. Moreover, the plurality of selection transistors 207 may not be disposed. Note that the number of the photoelectric conversion units 201 may be any number as long as there are two or more photoelectric conversion units 201. The photoelectric conversion device may also be provided with a microlens array including a plurality of microlenses. In this case, one of the microlenses (not illustrated) is disposed to correspond to one of the plurality of photoelectric conversion units 201. In the meantime, as another example, in the case where the photoelectric conversion device acquires a phase difference signal, a plurality of photoelectric conversion units may be disposed for a single microlens.

The photoelectric conversion units 201 are, for example, photodiodes. The photoelectric conversion units 201 each receive light incident on the pixel 200 and generate signal charge according to the incident light. The transfer transistors 202 are each driven by the transfer transistor drive pulse pTX to transfer the signal charge generated in the photoelectric conversion units 201 to the FD unit 203. The FD unit 203 functions as a charge-to-voltage conversion unit that temporarily holds the signal charge input from the photoelectric conversion units 201 and simultaneously converts the held signal charge into a voltage signal. The FD capacitance switching transistor 204 is driven by the FD capacitance switching pulse pFDINC to switch the capacitance of the FD unit 203. By turning the FD capacitance switching transistor 204 on, capacitance equivalent to the gate capacitance of the FD capacitance switching transistor 204 can be added to the FD unit 203. The reset transistor 205 is driven by the reset transistor drive pulse pRES. At that time, the FD unit 203 can be reset by turning the reset transistor 205 and the FD capacitance switching transistor 204 on at the same time. The amplifying transistors 206 each amplify the signal converted by the FD unit 203. The selection transistors 207 are each driven by the row selection drive pulse pSEL and output the amplified signal obtained by a corresponding one of the amplifying transistors 206 to any corresponding one of the first output lines 105-1 to 105-6 on a pixel row by pixel row basis. That is, the selection transistors 207 each select the first output line 105 that outputs the amplified signal from among the plurality of first output lines 105-1 to 105-6. As a result, the first output line 105 outputs the signal according to the potential of the FD unit 203.

In order to distinguish between the first output lines 105, identification numbers (1, 2, 3, 4, . . . ) are added at the end of the reference symbols of the first output lines 105. Hereinafter, if it is necessary to distinguish between the first output lines 105, identification numbers are added at the end of the reference symbols of the components of the first output lines 105. However, if it is not necessary to distinguish between the first output lines 105, identification numbers at the end of the reference symbols of the components of the first output lines 105 are omitted. Furthermore, identification numbers (1, 2, 3, 4, . . . ) are similarly added to the second output lines 405, which will be described later.

FIGS. 10A, 10B, and 10C are plan views illustrating an example of the layout of each pixel 200 included in the photoelectric conversion device. Note that FIGS. 10B and 10C are the same as FIGS. 5B and 5C illustrating the modification of the first embodiment.

Note that the pixels 200 illustrated in FIGS. 10A, 10B, and 10C have common components. Therefore, identification numbers (1, 2, 3, 4, . . . ) are added at the end of the reference symbols of the components of the pixels 200 in order to distinguish between the components of the pixels 200. Hereinafter, if it is necessary to distinguish between the components of the pixels 200, identification numbers are added at the end of the reference symbols of the components of the pixels 200. However, if it is not necessary to distinguish between the components of the pixels 200, the identification numbers at the end of the reference symbols of the components of the pixels 200 are omitted.

As illustrated in FIG. 10A, the first pixel 200-1 and the second pixel 200-2 are disposed next to each other in a column direction. The first pixel 200-1 includes the first pixel transistor region 402-1, the first photoelectric conversion unit 201-1, and a third photoelectric conversion unit 201-1′. In addition, in a plan view relative to the main surface of the pixel substrate 101, the FD unit 203 is disposed between the first photoelectric conversion unit 201-1 and the third photoelectric conversion unit 201-1′. The second pixel 200-2 includes the second pixel transistor region 402-2, the second photoelectric conversion unit 201-2, and a fourth photoelectric conversion unit 201-2′. In addition, in a plan view relative to the main surface of the pixel substrate 101, the FD unit 203 is disposed between the second photoelectric conversion unit 201-2 and the fourth photoelectric conversion unit 201-2′. Note that the pixel transistor region 402 is a region where the transfer transistors 202, the FD unit 203, the reset transistor 205, and the amplifying transistors 206 are disposed.

Also, within a single pixel 200, the photoelectric conversion units 201 and the corresponding transfer transistors 202 are disposed in a column direction. Moreover, within a single pixel 200, the photoelectric conversion units 201, the corresponding amplifying transistors 206, and the corresponding selection transistors 207 are disposed in a row direction. Also, within a single pixel 200, the photoelectric conversion units 201, the FD unit 203, the FD capacitance switching transistor 204, and the reset transistor 205 are disposed in a row direction and a column direction. Thus, the photoelectric conversion units 201 and the pixel transistor region 402 are disposed in a row direction and a column direction. Furthermore, in a plan view relative to the main surface of the pixel substrate 101, the FD unit 203 and the amplifying transistors 206 are disposed on a straight line along the longer-side direction of the second output lines 405. Also, in a plan view relative to the main surface of the pixel substrate 101, the FD unit 203 and the transfer transistors 202 are disposed on a straight line along the shorter-side direction of the second output lines 405. Also, in a plan view relative to the main surface of the pixel substrate 101, the FD unit 203 and the photoelectric conversion units 201 are disposed on a straight line along the longer-side direction of the second output lines 405. Moreover, in a plan view relative to the main surface of the pixel substrate 101, the second wiring 404 connecting the FD unit 203 and the gates of the amplifying transistors 206 and the photoelectric conversion units 201 are disposed on a straight line along the shorter-side direction of the second output lines 405.

The gate of each transistor is connected to a corresponding one of drive control lines that output pRES, pSEL, pTX, and pFDINC. Note that the above-described drive control lines are included in the second wiring layer M2. The source or drain of each selection transistor 207 is connected to either a corresponding one of the first output lines 105 or the second output lines 405, which will be described later, via the first wiring 403.

In a plan view relative to the main surface of the pixel substrate 101, the region in which the first output lines 105 overlap with at least a portion of the pixel transistor region 402 serves as the first region 401. Note that the first region 401 may include, in a plan view relative to the main surface of the pixel substrate 101, a region between the multiple first output lines 105 that overlaps with at least a portion of the pixel transistor region 402. In addition, in a plan view relative to the main surface of the pixel substrate 101, the region outside the first region 401 and present between the first pixel transistor region 402-1 and the second pixel transistor region 402-2 serves as the third region 410.

FIG. 10B illustrates a plan layout of the third wiring layer M3. Note that the third wiring layer M3 is provided on top of the second wiring layer M2. The third wiring layer M3 is provided with the second output lines 405-1 to 405-6. Also, in FIG. 10B, taking into consideration the third region 410 disposed between multiple pixels 200 adjacent to each other in a column direction, the first region 401 is present between multiple third regions 410 in a plan view relative to the main surface of the pixel substrate 101. Note that the first pixel 200-1 and the second pixel 200-2 are disposed next to each other in the longer-side direction of the second output lines 405.

In a plan view relative to the main surface of the pixel substrate 101, the second output lines 405 are positioned not to overlap with the first region 401. That is, in a plan view relative to the main surface of the pixel substrate 101, the second output lines 405 are positioned not to overlap with the FD unit 203. Also, in a plan view relative to the main surface of the pixel substrate 101, the second output lines 405 are positioned not to overlap with the second wiring 404 connecting the FD unit 203 and the gates of the amplifying transistors 206. Thus, in a plan view relative to the main surface of the pixel substrate 101, an end portion of each of the second output lines 405-1 to 405-6 intersecting with respect to the longer-side direction of the second output lines 405-1 to 405-6 is positioned to overlap with at least a portion of the third region 410. Note that both end portions of each of the second output lines 405-1 to 405-6 intersecting with respect to the longer-side direction of the second output lines 405-1 to 405-6 may be positioned to overlap with at least a portion of the third region 410.

FIG. 10c illustrates a plan layout of the fourth wiring layer M4. Note that the fourth wiring layer M4 is provided on top of the third wiring layer M3. The fourth wiring layer M4 is provided with the first output lines 105-1 to 105-6. The first output lines 105-1 to 105-6 are electrically connected to the second output lines 405-1 to 405-6, respectively. Here, portions of the first output lines 105 positioned to overlap with at least a portion of the third region 410 in a plan view relative to the main surface of the pixel substrate 101 are defined as the backing wiring portions 407. Also, portions of the first output lines 105 positioned to overlap with at least a portion of the first region 401 in a plan view relative to the main surface of the pixel substrate 101 are defined as the non-backing wiring portions 408.

As illustrated in FIGS. 10A, 10B, and 10C, because the second output lines 405 are not provided at positions that overlap with at least a portion of the first region 401 in a plan view relative to the main surface of the pixel substrate 101, close proximity between the FD unit 203 and the second output lines 405 can be prevented. This configuration can suppress the occurrence of crosstalk due to an increase in the parasitic capacitance between the FD unit 203 and the second output lines 405. This configuration can also suppress the occurrence of crosstalk likewise due to an increase in the parasitic capacitance between the second wiring 404 and the second output lines 405.

In the meantime, by providing the second output lines 405, electrically connected to the first output lines 105, at positions that overlap with at least a portion of the third region 410 in a plan view relative to the main surface of the pixel substrate 101, the output lines are configured as two layers of the third wiring layer M3 and the fourth wiring layer M4. This configuration can reduce the probability of a manufacturing defect occurring that a signal from a pixel will not be output correctly due to a break in any output line during the manufacturing process. As a result, the yield can be improved.

Accordingly, the present embodiment enables both yield improvement and crosstalk suppression by providing the backing wiring portions 407 and the non-backing wiring portions 408 in the first output lines 105.

Note that, for the configuration of the present embodiment, shield wiring may be further provided in the third wiring layer M3, as described in the second embodiment. Also, for the configuration of the present embodiment, the size of the range of the first region 401 may be changed, as described in the third embodiment. Moreover, for the configuration of the present embodiment, shield wiring may be further provided in the third wiring layer M3 to change the size of the range of the first region 401, as described in the fourth embodiment.

Although the present embodiment describes a form in which one FD unit 203, which is an impurity diffusion region, is shared by a plurality of photoelectric conversion units 201, other forms may be used. For example, a first FD unit corresponding to the first photoelectric conversion unit 201-1 and a second FD unit corresponding to the third photoelectric conversion unit 201-1′ are provided. The first FD unit and the second FD unit are electrically isolated within the semiconductor substrate, either through an insulator or a PN junction. The first FD unit and the second FD unit may be connected by wiring. This wiring is connected to the gates of the amplifying transistors 206. Even with this form, signal charge of the first photoelectric conversion unit 201-1 and signal charge of the third photoelectric conversion unit 201-1′ can be respectively input to the gates of the amplifying transistors 206.

### Sixth Embodiment

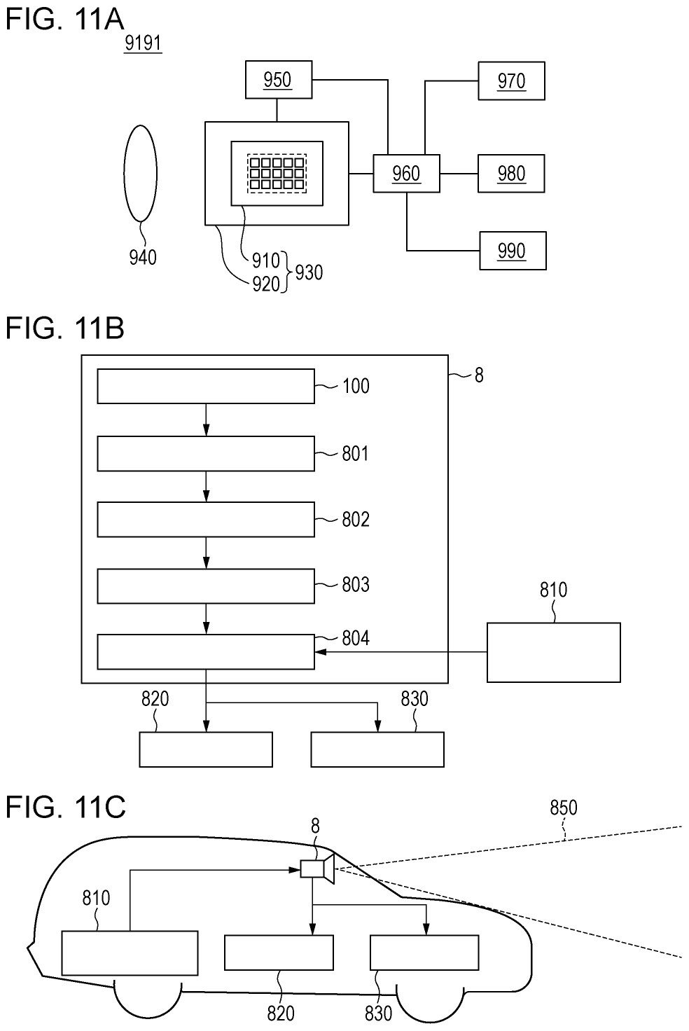

A sixth embodiment is applicable to any of the first to fifth embodiments. FIG. 11A is a schematic diagram illustrating equipment 9191 provided with a semiconductor device 930 of the present embodiment. The photoelectric conversion device of each of the above embodiments can be used for the semiconductor device 930. The equipment 9191 provided with the semiconductor device 930 will be described in detail. The semiconductor device 930 can include a semiconductor component 910. The semiconductor device 930 can include, in addition to the semiconductor component 910, a package 920 that houses the semiconductor component 910. The package 920 can include a base to which the semiconductor component 910 is secured, and a lid made of glass, for example, which faces the semiconductor component 910. The package 920 may further include a bonding member, such as a bonding wire or bump, that connects a terminal provided on the base with a terminal provided on the semiconductor component 910.

The equipment 9191 can include at least any of an optical device 940, a control device 950, a processing device 960, a display device 970, a storage device 980, and a mechanical device 990. The optical device 940 corresponds to the semiconductor device 930. The optical device 940 includes a lens, a shutter, and a mirror, for example, and is provided with an optical system that directs light to the semiconductor device 930. The control device 950 controls the semiconductor device 930. The control device 950 is a photoelectric conversion device such as an application-specific integrated circuit (ASIC), for example.

The processing device 960 processes signals output from the semiconductor device 930. The processing device 960 is a photoelectric conversion device such as a central processing unit (CPU) or ASIC, for example, for configuring an analog front-end (AFE) or a digital front-end (DFE). The display device 970 is an electroluminescent (EL) display device or a liquid crystal display device that displays information (images) obtained by the semiconductor device 930. The storage device 980 is a magnetic device or semiconductor device that stores information (images) obtained by the semiconductor device 930. The storage device 980 is volatile memory, such as static random-access memory (SRAM) or dynamic RAM (DRAM), or non-volatile memory, such as flash memory or a hard disk drive.

The mechanical device 990 has a movable part or a propulsion part, such as a motor or an engine. In the equipment 9191, a signal output from the semiconductor device 930 is displayed on the display device 970 or transmitted externally by a communication device (not illustrated) included in the equipment 9191. To that end, the equipment 9191 preferably further include the storage device 980 and the processing device 960 in addition to storage circuitry and computing circuitry of the semiconductor device 930. The mechanical device 990 may be controlled based on signals output from the semiconductor device 930.

The equipment 9191 is also suitable for electronic equipment such as information terminals (e.g., smartphones and wearable terminals) having image shooting functions, and cameras (e.g., interchangeable lens cameras, compact cameras, video cameras, and surveillance cameras). The mechanical device 990 in the camera can drive the components of the optical device 940 for zooming, focusing, and shuttering operations. Alternatively, the mechanical device 990 in the camera can move the semiconductor device 930 for anti-vibration operation.

Moreover, the equipment 9191 may be transportation equipment, such as a vehicle, a ship, a flying vehicle (drone, aircraft, etc.), and the like. The mechanical device 990 in the transportation equipment can be used as a moving device. The equipment 9191 as transportation equipment is suitable for transporting the semiconductor device 930 or for assisting and/or automating driving (maneuvering) with image shooting functions. The processing device 960 for assisting and/or automating driving (maneuvering) may perform processing for operating the mechanical device 990 as a moving device based on information obtained by the semiconductor device 930. Alternatively, the equipment 9191 may be medical equipment such as an endoscope, measuring equipment such as a ranging sensor, analytical equipment such as an electron microscope, office equipment such as a copying machine, or industrial equipment such as a robot.

According to the above-described embodiments, good pixel characteristics can be obtained. Thus, the photoelectric conversion device can have an enhanced value. Enhancing the value here includes at least any of the following: adding functions, improving performance, improving characteristics, improving reliability, improving production yield, reducing environmental impact, reducing costs, miniaturizing, and reducing weight.

Therefore, if the semiconductor device 930 according to the present embodiment is used in the equipment 9191, the equipment can also have an enhanced value. For example, the semiconductor device 930 can be mounted on transportation equipment to obtain excellent performance when capturing images outside the transportation equipment or measuring the external environment. Therefore, in manufacturing and selling the transportation equipment, deciding to mount the photoelectric conversion device according to the present embodiment on the transportation equipment is advantageous in enhancing the performance of the transportation equipment itself. In particular, the semiconductor device 930 is suitable for transportation equipment that uses information obtained by the photoelectric conversion device to provide driving assistance and/or autonomous driving of the transportation equipment.

A photoelectric conversion system and a mobile entity according to the present embodiment will be described with reference to FIGS. 11B and 11C.

FIG. 11B illustrates an example of a photoelectric conversion system related to an in-vehicle camera. A photoelectric conversion system 8 includes the photoelectric conversion device 100. The photoelectric conversion device 100 is a photoelectric conversion device (imaging device) according to any of the above embodiments. The photoelectric conversion system 8 includes an image processing unit 801, which performs image processing on a plurality of pieces of image data obtained by the photoelectric conversion device 100, and a parallax acquisition unit 802, which calculates a parallax (phase differences of parallax images) from the plurality of pieces of image data obtained by the photoelectric conversion system 8. Here, the photoelectric conversion system 8 may be equipped with an optical system (not illustrated) such as a lens, a shutter, a mirror, and the like for directing light to the photoelectric conversion device 100. In addition, a plurality of photoelectric conversion units, which are substantially conjugated with the pupils of the optical system, may be disposed in the pixels of the photoelectric conversion device 100. For example, the plurality of photoelectric conversion units substantially conjugated with the pupils are disposed corresponding to a single microlens. The plurality of photoelectric conversion units receives light beams that have passed through different positions of the pupils of the optical system, which then allows the photoelectric conversion device 100 to output image data corresponding to the light beams that have passed through the different positions. Then, the parallax acquisition unit 802 may calculate the parallax using the output image data. The photoelectric conversion system 8 also includes a distance acquisition unit 803, which calculates a distance to an object based on the calculated parallax, and a collision determination unit 804, which determines whether there is a possibility of collision based on the calculated distance. Here, the parallax acquisition unit 802 and the distance acquisition unit 803 are examples of a distance information acquisition unit configured to acquire distance information to an object. That is, distance information is information related to parallax, defocus amount, distance to an object, or the like. The collision determination unit 804 may use any of these pieces of distance information to determine the possibility of collision. Note that distance information may be acquired by time of flight (ToF). The distance information acquisition unit may be implemented by specially-designed hardware or may be implemented by a software module. The distance information acquisition unit may also be implemented by a field programmable gate array (FPGA), ASIC, or a combination thereof.

The photoelectric conversion system 8 is connected to a vehicle information acquisition device 810 and can acquire vehicle information such as vehicle speed, yaw rate, steering angle, and so forth. The photoelectric conversion system 8 is also connected to a control electronic control unit (ECU) 820, which is a control device that outputs a control signal for generating a braking force for the vehicle, based on a determination result obtained by the collision determination unit 804. The photoelectric conversion system 8 is also connected to a warning device 830, which emits alerts to the driver based on the determination result obtained by the collision determination unit 804. For example, if the possibility of collision is high as a result of the determination of the collision determination unit 804, the control ECU 820 performs vehicle control to apply brakes, return the accelerator, and/or suppress the engine power to avoid collisions and reduce damage. The warning device 830 alerts the user by emitting sound alarms, displaying warning information on screens of the car navigation system, and/or applying vibrations to the seatbelt or steering wheel.

In the present embodiment, the surroundings of the vehicle, such as the front or rear, are imaged by the photoelectric conversion system 8.

FIG. 11C illustrates the photoelectric conversion system 8 in the case of capturing images of the vehicle front (imaging range 850). The vehicle information acquisition device 810 sends an instruction to the photoelectric conversion system 8 or the photoelectric conversion device 100. Such a configuration can further improve the accuracy of ranging.

The above describes an example of applying control to avoid collisions with other vehicles, but the above can also be applied to control for autonomous driving following other vehicles and control for autonomous driving to stay within the lane boundaries. Furthermore, the photoelectric conversion system 8 is not limited to vehicles such as automobiles, and can be applied to mobile entities (moving devices) such as ships, aircraft, or industrial robots, for example. In addition, the photoelectric conversion system 8 is not limited to mobile entities, and can be applied to equipment that widely uses object recognition, such as an intelligent transport system (ITS).

In the present specification, expressions such as “A or B”, “at least one of A and B”, “at least one of A and/or B”, and so forth can include all possible combinations of the listed items unless specifically defined. That is, the above expressions are understood to disclose all of the following cases: when at least one A is included, when at least one B is included, and when at least one A and at least one B are both included. The same similarly applies to combinations of three or more elements.

The embodiments described above can be changed as appropriate within the scope of the disclosed technical concepts. It should be noted that the disclosure in the present specification includes not only what is described in the present specification, but also all matters that can be understood from the present specification as well as the drawings appended thereto. Additionally, the disclosure in the present specification encompasses the complement of the concepts described in the present specification. That is, if there is the description “A is greater than B” in the present specification, for example, even if the description “A is not greater than B” is omitted, it can be said that the present specification discloses that “A is not greater than B”. This is because if “A is greater than B” is described, it is assumed that cases where “A is not greater than B” are taken into consideration.

According to the present disclosure, a photoelectric conversion device whose configuration includes output lines is capable of both improving yield and suppressing crosstalk.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-166156, filed Oct. 17, 2022, and No. 2023-169953, filed Sep. 29, 2023, which are hereby incorporated by reference herein in their entirety.

What is claimed is:

1. A photoelectric conversion device comprising:
a pixel substrate,
wherein the pixel substrate includes:
a photoelectric conversion unit configured to generate signal charge according to incident light,
a floating diffusion unit configured to receive the signal charge as input,
a pixel transistor region including the floating diffusion unit,
a first output line configured to output a signal according to a potential of the floating diffusion unit,
a second output line electrically connected to the first output line,
a first region, in a plan view relative to a main surface of the pixel substrate, where the first output line overlaps with at least a portion of the pixel transistor region, and
a second region, in the plan view relative to the main surface, located outside the first region and where the second output line overlaps with at least a portion of the photoelectric conversion unit, and
wherein, in the plan view relative to the main surface, an end portion of the second output line intersecting with respect to a longer-side direction of the second output line is positioned to overlap with at least a portion of the second region.

2. The photoelectric conversion device according to claim 1, wherein, in the plan view relative to the main surface, the floating diffusion unit is positioned to overlap with at least a portion of the first region.

3. The photoelectric conversion device according to claim 1, wherein the pixel transistor region includes a transfer transistor configured to transfer the signal charge to the floating diffusion unit, an amplifying transistor configured to amplify the signal, and a reset transistor configured to reset the floating diffusion unit.

4. The photoelectric conversion device according to claim 3, wherein the pixel transistor region includes a selection transistor configured to select the first output line that outputs the signal from among a plurality of the first output lines, and a floating diffusion capacitance switching transistor configured to switch capacitance of the floating diffusion unit.

5. The photoelectric conversion device according to claim 3, wherein, in the plan view relative to the main surface, the floating diffusion unit and wiring connecting the floating diffusion unit and a gate of the amplifying transistor are positioned to overlap with at least a portion of the first region.

6. The photoelectric conversion device according to claim 4, wherein, in the plan view relative to the main surface, the floating diffusion unit, wiring connecting the floating diffusion unit and a gate of the amplifying transistor, the gate of the amplifying transistor, and the floating diffusion capacitance switching transistor are positioned to overlap with at least a portion of the first region.

7. The photoelectric conversion device according to claim 4, wherein, in the plan view relative to the main surface, the floating diffusion unit, wiring connecting the floating diffusion unit and a gate of the amplifying transistor, the amplifying transistor, the reset transistor, the selection transistor, and the floating diffusion capacitance switching transistor are positioned to overlap with at least a portion of the first region.

8. The photoelectric conversion device according to claim 1, wherein, in the plan view relative to the main surface, the second output line is positioned to overlap with at least a portion of the first output line.

9. The photoelectric conversion device according to claim 1, wherein, in a cross-sectional view relative to the main surface, the second output line is disposed between the first output line and the photoelectric conversion unit.

10. The photoelectric conversion device according to claim 9, wherein, in the cross-sectional view relative to the main surface, shield wiring is disposed between the first output line and the pixel transistor region.

11. The photoelectric conversion device according to claim 10, wherein, in the plan view relative to the main surface, the shield wiring is positioned to overlap with at least a portion of the first region.

12. The photoelectric conversion device according to claim 10, wherein the shield wiring is set to a reference voltage or a power supply voltage.

13. The photoelectric conversion device according to claim 1, wherein, in a case where a pixel is disposed on the pixel substrate, the pixel includes the photoelectric conversion unit, the floating diffusion unit, and the pixel transistor region, and, in the plan view relative to the main surface, the second region is a region included in the pixel.

14. The photoelectric conversion device according to claim 13, wherein a plurality of pixels, including the pixel, are disposed in a matrix, and, for each of columns where the plurality of pixels are disposed, a plurality of the first output lines is disposed.

15. The photoelectric conversion device according to claim 1, wherein, in the plan view relative to the main surface, the second output line is positioned not to overlap with the floating diffusion unit.

16. The photoelectric conversion device according to claim 1, wherein the pixel transistor region includes an amplifying transistor configured to amplify the signal, and, in the plan view relative to the main surface, the second output line is positioned not to overlap with wiring connecting the floating diffusion unit and a gate of the amplifying transistor.

17. The photoelectric conversion device according to claim 1, wherein a wiring layer is disposed on one side of two sides of the pixel substrate, and light is incident on the photoelectric conversion unit from the other side of the two sides of the pixel substrate.

18. The photoelectric conversion device according to claim 17, further comprising a circuit substrate, stacked on the one side of the pixel substrate, includes a peripheral circuit configured to process a signal output by the first output line.

19. A photoelectric conversion device comprising:
a pixel substrate having a first pixel and a second pixel,
wherein the first pixel and the second pixel each include:
a photoelectric conversion unit configured to generate signal charge according to incident light,
a floating diffusion unit configured to receive the signal charge as input, and
a pixel transistor region including the floating diffusion unit,
wherein the pixel substrate further includes:
a first output line configured to output a signal according to a potential of the floating diffusion unit,
a second output line electrically connected to the first output line where the first pixel and the second pixel are adjacent to each other in a longer-side direction of the second output line,
a first region, in a plan view relative to a main surface of the pixel substrate, where the first output line overlaps with at least a portion of the pixel transistor region of the first pixel, and
a third region, in the plan view relative to the main surface, located outside the first region and located between the pixel transistor region included in the first pixel and the pixel transistor region included in the second pixel, and
wherein, in the plan view relative to the main surface, an end portion of the second output line intersecting with respect to the longer-side direction of the second output line is positioned to overlap with at least a portion of the third region.

20. The photoelectric conversion device according to claim 19, wherein the first pixel includes a first photoelectric conversion unit and a third photoelectric conversion unit, and the first photoelectric conversion unit and the third photoelectric conversion unit share the floating diffusion unit included in the first pixel.

21. The photoelectric conversion device according to claim 20, further comprising a plurality of microlenses, wherein one of the plurality of microlenses is disposed corresponding to the first photoelectric conversion unit, and another one of the plurality of microlenses is disposed corresponding to the third photoelectric conversion unit.

22. The photoelectric conversion device according to claim 20, wherein, in the plan view relative to the main surface, the floating diffusion unit included in the first pixel is disposed between the first photoelectric conversion unit and the third photoelectric conversion unit.

23. The photoelectric conversion device according to claim 20, wherein the pixel transistor region includes an amplifying transistor configured to amplify the signal, and the floating diffusion unit and a gate of the amplifying transistor are connected via wiring.

24. The photoelectric conversion device according to claim 19, wherein the first pixel includes a first photoelectric conversion unit and a third photoelectric conversion unit, the pixel transistor region includes an amplifying transistor configured to amplify the signal, the amplifying transistor has a gate connected to the floating diffusion unit, and the signal charge corresponding to the first photoelectric conversion unit and the signal charge corresponding to the third photoelectric conversion unit are input to the gate.

25. The photoelectric conversion device according to claim 19,
wherein the pixel transistor region includes a transfer transistor configured to transfer the signal charge to the floating diffusion unit, and an amplifying transistor configured to amplify the signal, and
wherein, in the plan view relative to the main surface, the floating diffusion unit and the amplifying transistor are disposed on a straight line along a longer-side direction of the second output line, and the floating diffusion unit and the transfer transistor are disposed on a straight line along a shorter-side direction of the second output line.

26. The photoelectric conversion device according to claim 19,
wherein the pixel transistor region includes an amplifying transistor configured to amplify the signal, and
wherein, in the plan view relative to the main surface, the floating diffusion unit and the photoelectric conversion unit are disposed on a straight line along a longer-side direction of the second output line, and wiring connecting the floating diffusion unit and a gate of the amplifying transistor and the photoelectric conversion unit are disposed on a straight line along a shorter-side direction of the second output line.

27. Equipment comprising:
the photoelectric conversion device according to claim 1,
wherein the equipment further comprises at least one of:
an optical device configured to direct light to the photoelectric conversion device,
a control device configured to control the photoelectric conversion device,
a processing device configured to process a signal output from the photoelectric conversion device,
a display device configured to display information obtained by the photoelectric conversion device,
a storage device configured to store information obtained by the photoelectric conversion device, and
a mechanical device configured to operate based on information obtained by the photoelectric conversion device.
